(19) United States
(12) Patent Application Publication
(10) Pub. No.: US 2019/0348778 A1
(43) Pub. Date: Nov. 14, 2019

(54) Printed Circuit Board for Interconnecting Electrical Control Wires

(71) Applicants: Rodney Preston, Argyle, TX (US); Shawn Preston, Argyle, TX (US)

(72) Inventors: Rodney Preston, Argyle, TX (US); Shawn Preston, Argyle, TX (US)

(21) Appl. No.: 16/278,045

(22) Filed: Feb. 15, 2019

Related U.S. Application Data
(60) Provisional application No. 62/631,727, filed on Feb. 17, 2018.

(51) Int. Cl. H01R 9/24; H01R 43/20; H05K 1/11; H05K 1/18

(52) U.S. Cl. CPC H01R 9/2466; H01R 43/205; H01R 9/2475; H05K 2201/1034; H05K 1/181; H05K 2201/10356; H05K 1/11

(57) ABSTRACT

A method, system, and apparatus for interconnecting multiple wires using a printed circuit board and a plurality of terminal blocks attached to the circuit board. Each terminal block includes a plurality of corresponding connection terminals including at least a first connection terminal and a second connection terminal. The printed circuit board includes a first conductive connection path interconnecting the first corresponding connection terminal of each of the plurality of terminal blocks and a second conductive connection path interconnecting the second corresponding connection terminal of each of the plurality of terminal blocks. Each connection terminal includes a connector adapted to selectively secure a conductive wire to the connection terminal.

### RELATED APPLICATION

The present application claims the benefit of U.S. Provisional Application No. 62/631,727 filed on Feb. 17, 2018, incorporated herein by reference.

### TECHNICAL FIELD

The present disclosure relates generally to electrical connectors, and particularly, to a layered circuit board configured to connect multiple electrical control wires.

### BACKGROUND

When a communicating system such as an air conditioning system is zoned, there may be as many as eight independent zones that can be controlled by a central controller. Typically, each independent zone has four, 18-22 gauge, insulated, low-voltage control wires that connect the zone to a central Zoning Control Board. There are three major components of a communicating air conditioning system:
Communicating indoor furnace or fan coil;
The User Interface or thermostat; and
The Communicating outdoor compressor unit or heat pump.

All three of these components also use the four low-voltage control wires to connect to the Zoning Control Board. In a conventional wiring configuration, a system with eight independent zones will have 44 low-voltage control wires connected in a large twisted wad of wires connected with wire nuts and having jumpers between the wire nuts. Likewise, a system with four zones will have 24 low-voltage control wires. A conventional design may allow for only eight wiring connections. Making the connections using the conventional method (i.e., wire nuts) is very time consuming. It is also difficult to troubleshoot and provides a very poor appearance. Double lugging of any of the wires is not recommended since double lugging can cause many communication issues.

Another recurring problem with the conventional low-voltage communication wiring connections is that if there is a problem with just one of these wires, the entire wad of wires must be disconnected, then reconnected using freshly stripped wires. The wires also tend to corrode over time. The corrosion will compound the communication problems inside the wad of wires in the wire nut.

Depending on the number of zones involved, a technician may spend many hours, or sometimes days, troubleshooting a system.

### SUMMARY

The present disclosure describes an Interconnection Printed Circuit Board (I-PCB) that overcomes the disadvantages of the conventional wiring configuration. The I-PCB is configured to connect multiple control wires. The I-PCB can be configured to work with any control system that requires multiple low-voltage connections. A particular exemplary embodiment described herein is configured to work with communicating, multi-zoned air conditioning systems. Communicating air conditioning controls communicate digitally over control wires using 18-22 gauge wire.

An exemplary embodiment of the I-PCB comprises a layered PCB that enables neat and organized control wiring connections to be made. The I-PCB may be installed either outside or inside associated equipment, or it may be mounted directly on a communicating zoning board. When using the I-PCB, each individual wire has its own connection point. Each connection is exposed and easy to see without disconnecting anything.

### BRIEF DESCRIPTION OF THE DRAWINGS

FIG. 1 is a top plan view of an exemplary embodiment of an Interconnection Printed Circuit Board (I-PCB) of the present disclosure;

FIG. 2 is a top plan view of an exemplary embodiment of a first interior connection layer (L1) of the I-PCB;

FIG. 3 is a top plan view of an exemplary embodiment of a second interior connection layer (L2) of the I-PCB;

FIG. 4 is a top plan view of the I-PCB of FIG. 1 with exemplary labels A-B-C-D for the installed connection terminals;

FIG. 5 (Prior Art) is a schematic view of conventional control-wire connections in an air conditioning control system; and

FIG. 6 is a schematic view of an exemplary embodiment of control-wire connections in an air conditioning control system utilizing the I-PCB.

FIG. 7 is a flow diagram of a method for interconnecting components using ab I-PCB.

### DETAILED DESCRIPTION

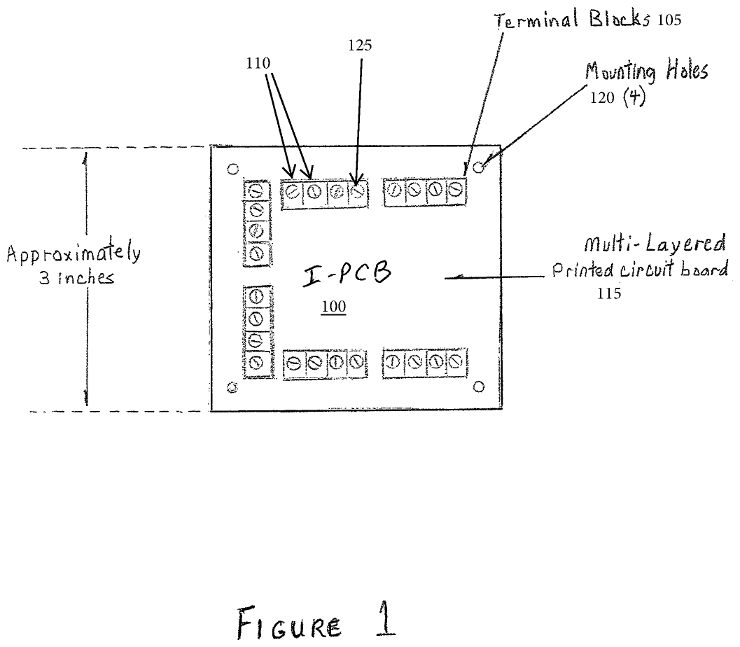

FIG. 1 is a top plan view of an exemplary embodiment of an Interconnection Printed Circuit Board (I-PCB) 100 of the present disclosure. FIG. 1 shows:
basic layout of six different terminal blocks 105;
a multi-layered printed circuit board substrate 115; and
approximate size of the board.

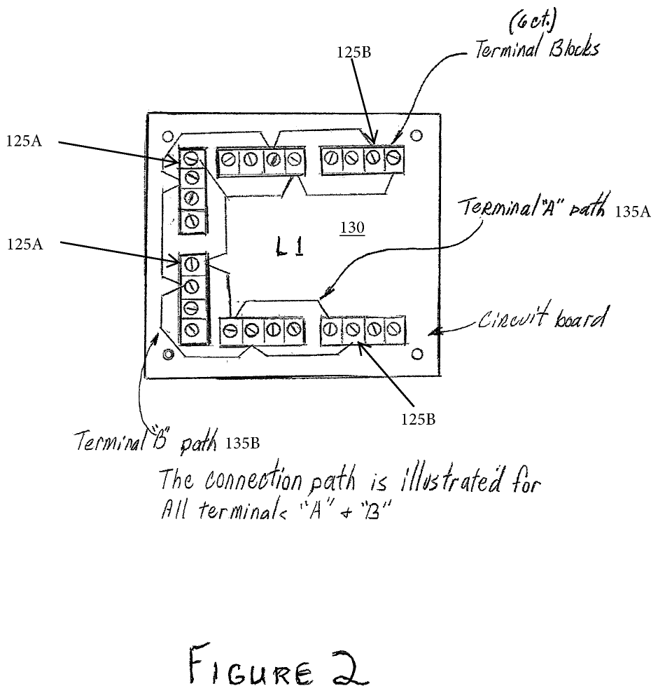

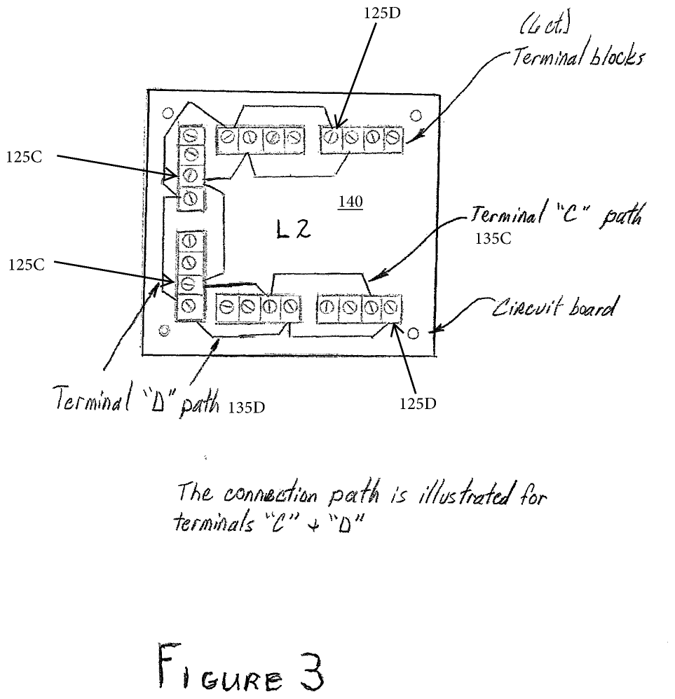

The I-PCB 100 includes terminal blocks 105 mounted on the surface of the multi-layered printed circuit board substrate 115. The multi-layered printed circuit board substrate 115, as depicted, includes four mounting holds 120 for mounting the I-PCB 100 to a desired surface and six terminal blocks 105. The terminal blocks 105 each include four connection terminals 110, each having a connector 125 (e.g., a screw as illustrated) for securing a wire or conductor to the connection terminal 110. As shown in FIGS. 2 and 3, the various terminal blocks 105 of the I-PCB 100 includes conductive interconnections (e.g., internal or on the surface) between corresponding connection terminals 110, without interconnecting non-corresponding connection terminals 110 (e.g., such that a conductive path does not exist between connection terminals 110 of the same terminal block 105, or between conductive interconnections that are connected to different connection terminals 110). Note that the terminal block size, count, and style can vary greatly. Although six terminal blocks 105, with four connection terminals 110 each, are shown in the exemplary embodiment described herein, the I-PCB 100 may be configured with a greater or lesser number of terminal blocks 105 and/or connection terminals 110, depending on the particular application for which the I-PCB 100 is used. There are many different manufacturers of terminal blocks 105 or connectors 125. Many if not all of them accomplish the task of attaching a wire or conductor to a circuit board. The connectors 125 may use screws, screw lugs, screws and washers, push pins, spring loaded clips, flip latches, and the like. The I-PCB 100 may not include any powered components or circuits other than the interconnections between corresponding connection terminals 110. Note also that circuit boards can vary in size or number of layers involved. The exemplary embodiment disclosed herein has two interior connection layers and may be approximately three inches square.

FIG. 2 is a top plan view of an exemplary embodiment of a first interior connection layer (L1) 130 of the I-PCB 100. The L1 layer 130 connects the “A” connection terminal 125A in each terminal block 105 to all of the other “A” connection terminals 125A using a conductive connection path 135A, and connects the “B” connection terminal 125B in each terminal block 105 to all of the other “B” connection terminals 125B in the six different terminal blocks 105 using a conductive connection path 135B. The conductive connection paths 135A, 135B can be included on a surface of the I-PCB 100 or the L1 layer 130 can be internal to the I-PCB 100 (e.g., underneath an exterior layer, cover, or coating).

FIG. 3 is a top plan view of an exemplary embodiment of a second interior connection layer (L2) 140 of the I-PCB 100. The L2 layer 140 connects the “C” connection terminal 125C in each terminal block 105 to all of the other “C” connection terminals 125C using a conductive connection path 135C, and connects the “D” connection terminal 125D in each terminal block 105 to all of the other “D” connection terminals 125D in the six different terminal blocks 105 using a conductive connection path 135D. Again, the conductive connection paths 135C, 135D can be included on a surface of the I-PCB 100 or the L2 layer 140 can be internal to the I-PCB 100 (e.g., underneath an exterior layer, cover, or coating). As an example, the L1 layer 130 and L2 layer 140 can be on opposite sides of the multi-layered printed circuit board substrate 115, with the surface of each side representing a different layer. Alternatively, the L1 layer 130 and L2 layer 140 can be included on different physical layers that are separately etched or deposited, or that are bonded together.

It should be well appreciated that different board layouts and different geometries of the interconnections may be utilized with the present invention as long as the connections connect like-lettered connection terminals (e.g., A-to-A-to-A, etc., B-to-B-to-B, etc. and so on).

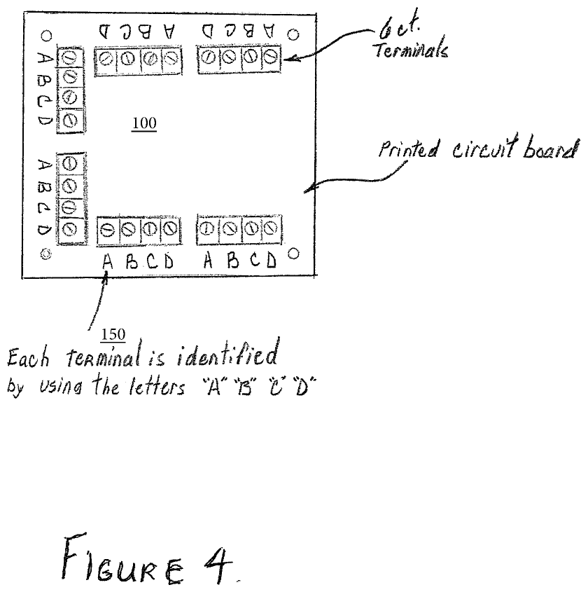

FIG. 4 is a top plan view of the I-PCB 100 of FIG. 1 with exemplary labels A-B-C-D 150 for the installed connection terminals in each of the six terminal blocks. The labels can enable a user of the I-PCB 100 to conveniently interconnect multiple components using multiple common control paths while helping ensure proper interconnections. The labels can include any human-readable indication (e.g., letters, numerals, symbols, or colors) to identify corresponding connection terminal among the various terminal blocks.

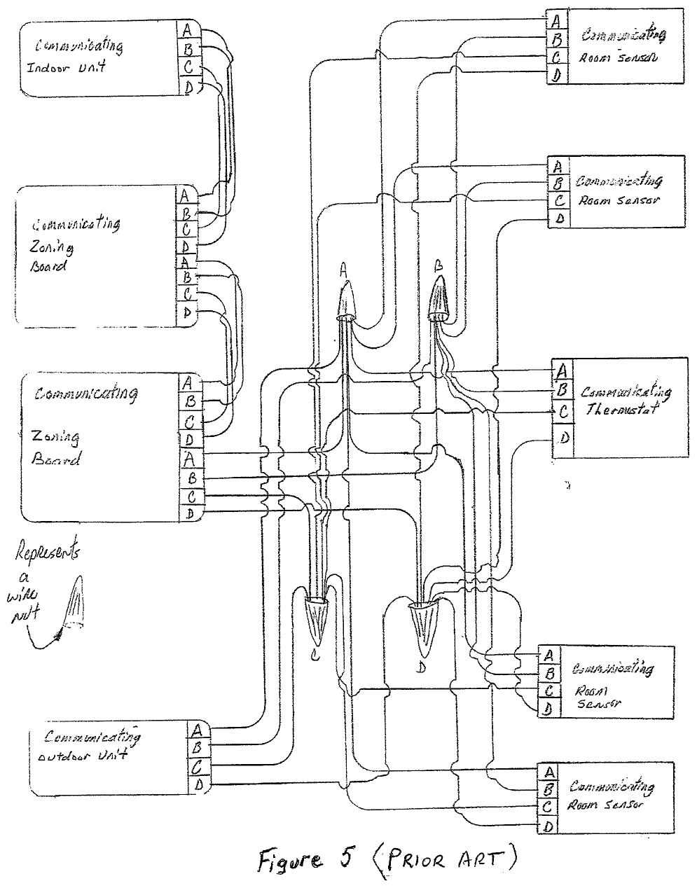

FIG. 5 is a schematic view of conventional control-wire connections in an exemplary air conditioning control system. In this example, the air conditioning system includes five zones. The zone count is limited to between one to eight zones maximum. Systems with eight zones are extremely complicated and difficult to wire correctly.

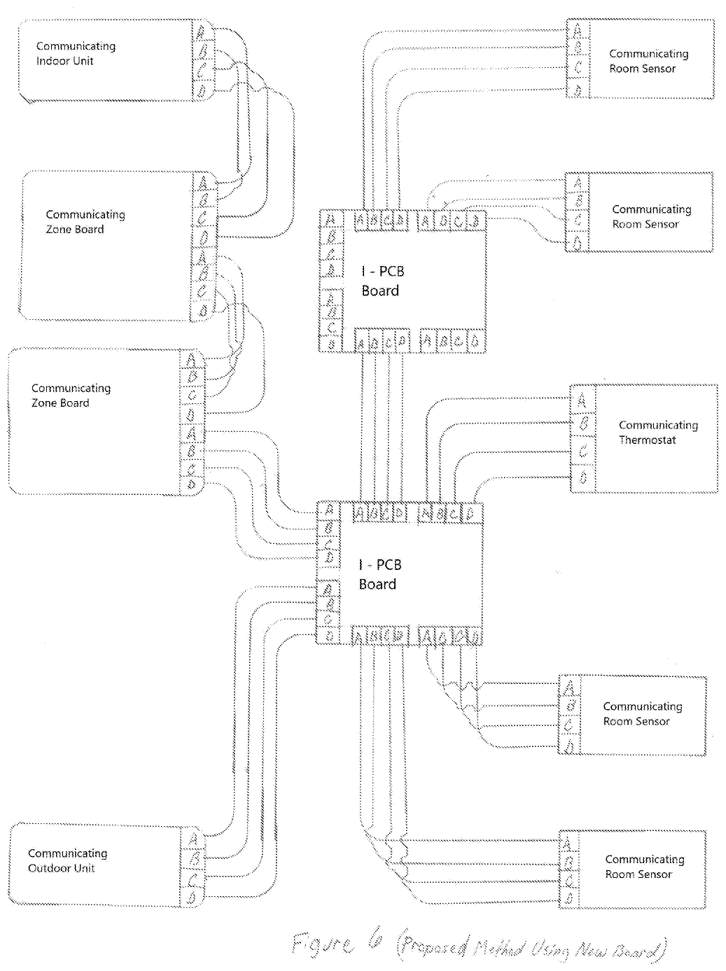

FIG. 6 is a schematic view of an exemplary embodiment of control-wire connections in an air conditioning control system 200 utilizing the I-PCB 100 of the present disclosure. The I-PCB 100 eliminates the need for wire nuts to interconnect the various wires. Each individual connection is exposed and identified. The use of the connection board allows room for up to three additional zones (using the unused connection terminals 110 in the upper I-PCB 100(1)) if needed. The air conditioning control system 200 includes a communicating indoor unit 205, a first communicating zoning board 210(1), a second communicating zoning board 210(2), a communicating outdoor unit 215, a first I-PCB 100(1), a second I-PCB 100(2) a communicating thermostat 220, and a plurality of communicating room sensors 225, each having corresponding connection terminals. By connecting wires to the various connection terminals 110 as illustrated, each A-labeled terminal for these various components 205, 210(1), 210(2), 215, 100(1), 100(2), 220, and 225 is thereby interconnected on a common control path. Likewise, each B-, C-, and D-labeled terminal, respectively, are also interconnected on respective common control paths.

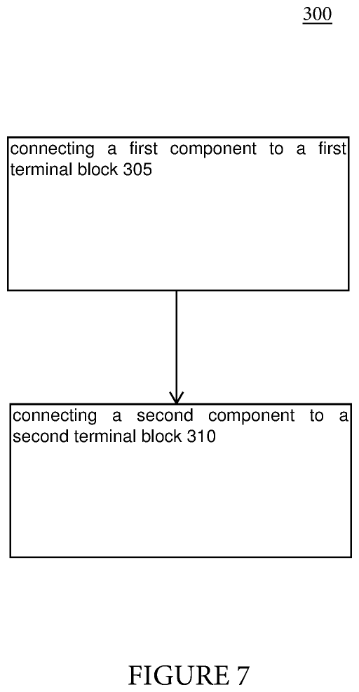

FIG. 7 is a flowchart of a method 300 for using the I-PCB 100 described above. The method 300 includes connecting a first component to a first terminal block at 305. The first connection can be made by connecting a first conductive wire between a first connection terminal of the first component and a first connection terminal of the first terminal block and connecting a second conductive wire between a second connection terminal of the first component and a second connection terminal of the first terminal block. A second component is connected at 310 to a second terminal block. The second connection can be made by connecting a third conductive wire between a first connection terminal of the second component and a first connection terminal of the second terminal block and connecting a fourth conductive wire between a second connection terminal of the second component and a second connection terminal of the second terminal block.

In the drawings and specification, there have been disclosed typical preferred embodiments of the disclosure and, although specific terms are employed, they are used in a generic and descriptive sense only and not for purposes of limitation.

What is claimed is:

1. An apparatus adapted to interconnect multiple wires comprising:
a printed circuit board;
a plurality of terminal blocks attached to the circuit board, with each terminal block including a plurality of corresponding connection terminals including at least a first connection terminal and a second connection terminal;
wherein the printed circuit board includes a first conductive connection path interconnecting the first corresponding connection terminal of each of the plurality of terminal blocks and a second conductive connection path interconnecting the second corresponding connection terminal of each of the plurality of terminal blocks; and
wherein each connection terminal includes a connector adapted to selectively secure a conductive wire to the connection terminal.

2. The apparatus of claim 1 wherein the printed circuit board includes a first layer and a second layer, with the first layer including the first conductive connection path and the second layer including the second conductive connection path.

3. The apparatus of claim 1 wherein the conductive wires comprise low-voltage wires.

4. The apparatus of claim 1 wherein the conductive wires comprise control wires for a multi-zoned heating or air-conditioning system.

5. The apparatus of claim 1 wherein each of the terminal blocks includes at least four connection terminals, and the printed circuit board further includes:
a third conductive connection path interconnecting a third corresponding connection terminal of each of the plurality of terminal blocks; and
a fourth conductive connection path interconnecting a fourth corresponding connection terminal of each of the plurality of terminal blocks.

6. The apparatus of claim 1 further comprising a plurality of human-readable labels, with each corresponding connection terminal having an associated substantially similar human-readable label that distinguishes the corresponding connection terminals from human-readable labels associated with the other connection terminals.

7. A method for interconnecting multiple components using an apparatus that includes:
a printed circuit board;
a plurality of terminal blocks attached to the circuit board, with each terminal block including a plurality of corresponding connection terminals including at least a first connection terminal and a second connection terminal;
wherein the printed circuit board includes a first conductive connection path interconnecting the first corresponding connection terminal of each of the plurality of terminal blocks and a second conductive connection path interconnecting the second corresponding connection terminal of each of the plurality of terminal blocks; and
wherein each connection terminal includes a connector adapted to selectively secure a conductive wire to the connection terminal;
the method comprising:
connecting a first component to a first of the plurality of terminal blocks by connecting a first conductive wire between a first connection terminal of the first component and a first connection terminal of the first terminal block and a second conductive wire between a second connection terminal of the first component and a second connection terminal of the first terminal block;
connecting a second component to a second of the plurality of terminal blocks by connecting a third conductive wire between a first connection terminal of the second component and a first connection terminal of the second terminal block and a fourth conductive wire between a second connection terminal of the second component and a second connection terminal of the second terminal block.

8. The method of claim 7 wherein the printed circuit board includes a first layer and a second layer, with the first layer including the first conductive connection path and the second layer including the second conductive connection path.

9. The method of claim 7 wherein the conductive wires comprise low-voltage wires.

10. The method of claim 7 wherein the conductive wires comprise control wires for a multi-zoned heating or air-conditioning system.

11. The method of claim 7 wherein each of the terminal blocks includes at least four connection terminals, the apparatus further including:
a third conductive connection path interconnecting a third corresponding connection terminal of each of the plurality of terminal blocks; and
a fourth conductive connection path interconnecting a fourth corresponding connection terminal of each of the plurality of terminal blocks; and
the method further comprising:
connecting the first component to the first terminal block by connecting a fifth conductive wire between a third connection terminal of the first component and a third connection terminal of the first terminal block and a sixth conductive wire between a fourth connection terminal of the first component and a fourth connection terminal of the first terminal block;
connecting the second component to the second terminal blocks by connecting a seventh conductive wire between a third connection terminal of the second component and a third connection terminal of the second terminal block and an eighth conductive wire between a fourth connection terminal of the second component and a fourth connection terminal of the second terminal block.

12. The method of claim 7 wherein the apparatus further includes a plurality of human-readable labels, with each corresponding connection terminal having an associated substantially similar human-readable label that distinguishes the corresponding connection terminals from human-readable labels associated with the other connection terminals.

13. A system comprising:
an interconnection apparatus, including:
a printed circuit board;
a plurality of terminal blocks attached to the circuit board, with each terminal block including a plurality of corresponding connection terminals including at least a first connection terminal and a second connection terminal;
wherein the printed circuit board includes a first conductive connection path interconnecting the first corresponding connection terminal of each of the plurality of terminal blocks and a second conductive connection path interconnecting the second corresponding connection terminal of each of the plurality of terminal blocks; and
wherein each connection terminal includes a connector adapted to selectively secure a conductive wire to the connection terminal;
a plurality of communicating devices, including a first communicating device and a second communicating device;
a first conductive wire connecting one of the first corresponding connection terminals of the interconnection apparatus to a first connection terminal of the first communicating device;
a second conductive wire connecting one of the second corresponding connection terminals of the interconnection apparatus to a second connection terminal of the first communicating device;
a third conductive wire connecting another of the first corresponding connection terminals of the interconnection apparatus to a first connection terminal of the second communicating device; and
a fourth conductive wire connecting another of the second corresponding connection terminals of the interconnection apparatus to a second connection terminal of the second communicating device.

14. The system of claim 13 wherein the printed circuit board includes a first layer and a second layer, with the first layer including the first conductive connection path and the second layer including the second conductive connection path.

15. The system of claim 13 wherein the conductive wires comprise low-voltage wires.

16. The system of claim 13 wherein the system comprises a multi-zoned heating or air-conditioning system.

17. The system of claim 13 wherein each of the terminal blocks includes at least four connection terminals, and the printed circuit board further includes:
a third conductive connection path interconnecting a third corresponding connection terminal of each of the plurality of terminal blocks; and
a fourth conductive connection path interconnecting a fourth corresponding connection terminal of each of the plurality of terminal blocks; and
the system further comprising:
a fifth conductive wire connecting another of the first corresponding connection terminals of the interconnection apparatus to a third connection terminal of the first communicating device;
a sixth conductive wire connecting one of the second corresponding connection terminals of the interconnection apparatus to a fourth connection terminal of the first communicating device;
a seventh conductive wire connecting another of the first corresponding connection terminals of the interconnection apparatus to a third connection terminal of the second communicating device; and
an eighth conductive wire connecting another of the second corresponding connection terminals of the interconnection apparatus to a fourth connection terminal of the second communicating device.

18. The system of claim 13 further comprising a plurality of human-readable labels, with each corresponding connection terminal having an associated substantially similar human-readable label that distinguishes the corresponding connection terminals from human-readable labels associated with the other connection terminals.

19. The system of claim 13 wherein the plurality of communicating devices comprise one of an outdoor unit for an air conditioning system, an indoor unit for an air conditioning system, a zoning board for an air conditioning system, a thermostat, or a room sensor.
